(19) United States
(12) Patent Application Publication
(10) Pub. No.: US 2007/0037333 A1
(43) Pub. Date: Feb. 15, 2007

(54) Work function separation for fully silicided gates

(75) Inventors: Luigi Colombo, Dallas, TX (US); James Joseph Chambers, Dallas, TX (US); Mark Robert Visokay, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/203,716

(22) Filed: Aug. 15, 2005

(51) Int. Cl. H01L 21/8234

(52) U.S. Cl. 438/197; 438/199

(57) ABSTRACT

Forming metal gate transistors that have different work functions is disclosed. In one example, a first metal is added to a first region of polysilicon overlying a dielectric that is on a substrate, and a second metal is added to a second region of the polysilicon. A third metal is formed over the first and second regions and a silicidation process if performed to form a first alloy in the first region and a second alloy in the second region. First and second segregated regions are also established adjacent to the dielectric in the first and second regions, respectively. The first and second metals serve to shift or adjust respective values of first and second work functions in the first and second regions.

### FIELD OF INVENTION

The present invention relates generally to semiconductor devices and more particularly to fabricating PMOS and NMOS transistor devices having metal gates.

### BACKGROUND OF THE INVENTION

It can be appreciated that several trends presently exist in the electronics industry. Devices are continually getting smaller, faster and requiring less power, while simultaneously being able to support and perform a greater number of increasingly complex and sophisticated functions. One reason for these trends is an ever increasing demand for small, portable and multifunctional electronic devices. For example, cellular phones, personal computing devices, and personal sound systems are devices which are in great demand in the consumer market. These devices rely on one or more small batteries as a power source while providing increased computational speed and storage capacity to store and process data, such as digital audio, digital video, contact information, database data and the like.

Accordingly, there is a continuing trend in the semiconductor industry to manufacture integrated circuits (ICs) with higher device densities. To achieve such high densities, there has been and continues to be efforts toward scaling down dimensions (e.g., at submicron levels) on semiconductor wafers. To accomplish such high densities, smaller feature sizes, smaller separations between features and layers, and/or more precise feature shapes are required, such as metal interconnects or leads, for example. The scaling-down of integrated circuit dimensions can facilitate faster circuit performance and/or switching speeds, and can lead to higher effective yield in IC fabrication processes by providing or ‘packing’ more circuits on a semiconductor die and/or more die per semiconductor wafer, for example.

One way to increase packing densities is to decrease the thickness of transistor gate dielectrics to shrink the overall dimensions of transistors, where a very large number of transistors are commonly used in IC's and electronic devices. Transistor gate dielectrics (e.g., silicon dioxide or nitrided silicon dioxide) have previously had thicknesses on the order of about 10 nm or more, for example. More recently, however, this has been reduced considerably to reduce transistor sizes and facilitate improved performance. Thinning gate dielectrics can have certain drawbacks, however. For example, a polycrystalline silicon (“polysilicon”) gate overlies the thin gate dielectric, and polysilicon naturally includes a depletion region where it interfaces with the gate dielectric. This depletion region can provide an insulative effect rather than conductive behavior, which is desired of the polysilicon gate since the gate is to act as an electrode for the transistor.

By way of example, if the depletion region acts like a 0.8 nm thick insulator and the gate dielectric is 10-nm thick, then the depletion region effectively increases the overall insulation between the gate and an underlying transistor channel by eight percent (e.g., from 10 nm to 10.8 nm). It can be appreciated that as the thickness of gate dielectrics are reduced, the effect of the depletion region can have a greater impact on dielectric behavior. For example, if the thickness of the gate dielectric is reduced to 2 nm, the depletion region would effectively increase the gate insulator by about 40 percent (e.g., from 2 nm to 2.8 nm). This increased percentage significantly reduces the benefits otherwise provided by thinner gate dielectrics.

Metal gates can be used to mitigate adverse affects associated with the depletion region phenomenon because, unlike polysilicon, little to no depletion region manifests in metal. Interestingly enough, metal gates were commonly used prior to the more recent use of polysilicon gates. An inherent limitation of such metal gates, however, led to the use of polysilicon gates. In particular, the use of a single work function metal proved to be a limitation in high performance circuits that require dual work function electrodes for low power consumption. The work function is the energy required to move an electron from the Fermi level to the vacuum level. In modern CMOS circuits, for example, both p-channel MOS transistor devices (“PMOS”) and n-channel MOS transistor devices (“NMOS”) are generally required, where a PMOS transistor requires a work function on the order of 5 eV and an NMOS transistor requires a work function on the order of 4 eV. A single metal can not be used, however, to produce a metal gate that provides such different work functions. Polysilicon gates are suited for application in CMOS devices since some of the gates can be substitutionally doped in a first manner to achieve the desired work function for PMOS transistors and other gates can be substitutionally doped in a second manner to achieve the desired work function for NMOS transistors. However, polysilicon gate suffer from the aforementioned gate depletion.

Consequently, it would be desirable to be able to form metal gate transistors having different work functions so that transistor gate dielectrics can be reduced to shrink the overall size of transistors and thereby increase packing densities.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present invention relates to forming transistors having metal gates, where the metal gates have different work functions so as to correspond to that of different transistor types, such as NMOS and PMOS transistors, for example. The metal gates of the transistors allow device dimensions, such as gate dielectric thicknesses, for example, to be reduced to facilitate increased packing densities. Additionally, the transistors can be efficiently formed as part of a CMOS fabrication process.

According to one or more aspects of the present invention, a method of forming metal gate transistors is disclosed. The method includes selectively masking off a layer of polysilicon overlying a dielectric on a semiconductor substrate so that the polysilicon is exposed in a first region, but not in a second region. A first metal is added to the polysilicon in the first region, where the first metal serves to shift a first work function in the first region. The polysilicon is then again selectively masked off, but this time so that it is exposed in the second region, but not in the first region. A second metal is added to the polysilicon in the second region, where the second metal serves to shift a second work function in the second region. A third metal is then formed over the first and second regions, and one or more silicidation operations are performed to form a first alloy in the first region and a second alloy in the second region. The first and second metals are segregated out toward the dielectric as a result of the silicidation processes such that first and second segregated regions are established in the first and second regions, respectively, adjacent to the dielectric. Finally, one or more transistors are then formed in the first and second regions.

According to one or more other aspects of the present invention, another method of forming metal gate transistors is disclosed. The method includes forming a first metal over a layer of polysilicon overlying a dielectric on a semiconductor substrate. The first metal is selectively masked off so that it is exposed in a second region, but not in a first region. The exposed first metal is removed from the second region, and is imparted into the polysilicon in the first region, where the first metal serves to shift a first work function in the first region. A second metal is then formed over the first and second regions, and is selectively masked off so that it is exposed in the first region, but not in the second region. The exposed second metal is removed from the first region, and is imparted into the polysilicon in the second region, where the second metal serves to shift a second work function in the second region. A third metal is then formed over the first and second regions, and one or more silicidation operations are performed to form a first alloy in the first region and a second alloy in the second region. The first and second metals are segregated out toward the dielectric as a result of the silicidation processes such that first and second segregated regions are established in the first and second regions, respectively, adjacent to the dielectric. Finally, one or more transistors are formed in the first and second regions.

According to one or more other aspects of the present invention, yet another method of forming metal gate transistors is disclosed. The method includes forming a third metal over a layer of polysilicon overlying a dielectric on a semiconductor substrate. The third metal is selectively masked off so that it is exposed in a first region, but not in a second region. A first metal is then applied to the first region, where the first metal serves to shift a first work function in the first region. The third metal is then again selectively masked off, but this time so that it is exposed in a second region, but not in a first region. A second metal is then applied to the second region, where the second metal serving to shift a second work function in the second region. One or more silicidation operations are then performed to form a first alloy in the first region and a second alloy in the second region. The first and second metals are segregated out toward the dielectric as a result of the silicidation processes such that first and second segregated regions are established in the first and second regions, respectively, adjacent to the dielectric. Finally, one or more transistors are formed in the first and second regions.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1 is a flow diagram illustrating an exemplary methodology for forming metal gate transistors according to one or more aspects of the present invention.

FIGS. 2-9 are fragmentary cross sectional diagrams illustrating the formation of exemplary metal gate transistors according to one or more aspects of the present invention, such as the methodology set forth in FIG. 1.

FIG. 10 is a flow diagram illustrating another exemplary methodology for forming metal gate transistors according to one or more aspects of the present invention.

FIGS. 11-22 are fragmentary cross sectional diagrams illustrating the formation of exemplary metal gate transistors according to one or more aspects of the present invention, such as the methodology set forth in FIG. 10.

FIG. 23 is a flow diagram illustrating yet another exemplary methodology for forming metal gate transistors according to one or more aspects of the present invention.

FIGS. 24-31 are fragmentary cross sectional diagrams illustrating the formation of exemplary metal gate transistors according to one or more aspects of the present invention, such as the methodology set forth in FIG. 23.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. It will be appreciated that where like acts, events, elements, layers, structures, etc. are reproduced, subsequent (redundant) discussions of the same may be omitted for the sake of brevity. In the following description, for purposes of explanation, numerous specific details are set forth in order to provide a thorough understanding of one or more aspects of the present invention. It may be evident, however, to one of ordinary skill in the art that one or more aspects of the present invention may be practiced with a lesser degree of these specific details. In other instances, known structures are shown in diagrammatic form in order to facilitate describing one or more aspects of the present invention.

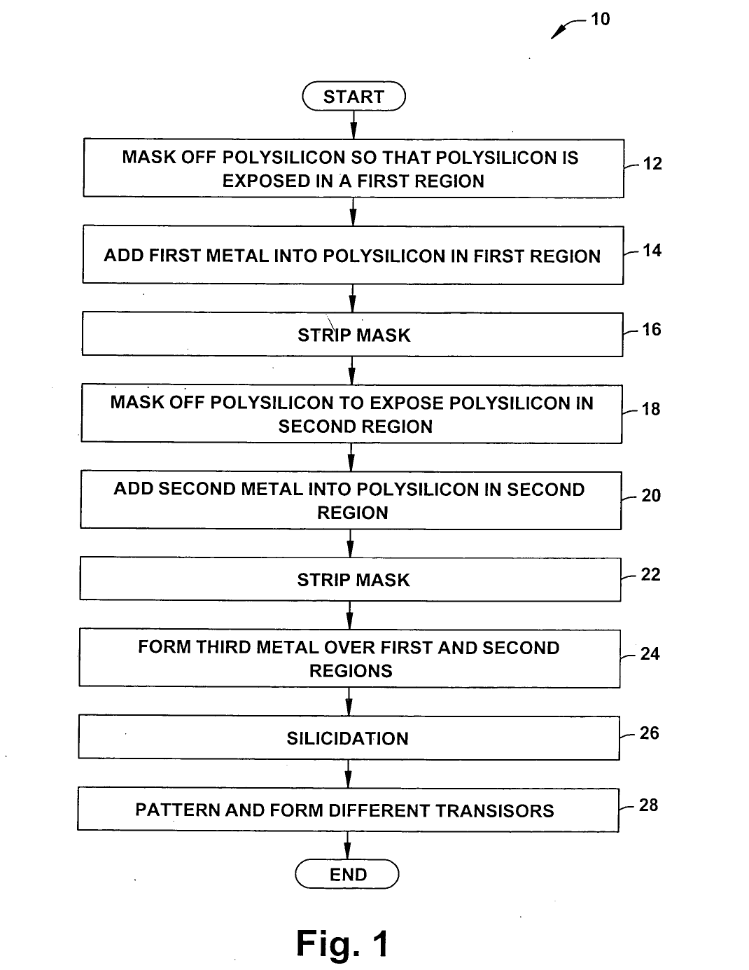

Turning to FIG. 1, an exemplary methodology 10 is illustrated for forming metal gate transistors according to one or more aspects of the present invention. As with all methodologies discussed herein, although the methodology 10 is illustrated and described hereinafter as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects of the present invention. Further, one or more of the acts may be carried out in one or more separate acts or phases. It will be appreciated that a methodology carried out according to one or more aspects of the present invention may be implemented in association with the formation and/or processing of structures illustrated and described herein as well as in association with other structures not illustrated or described herein.

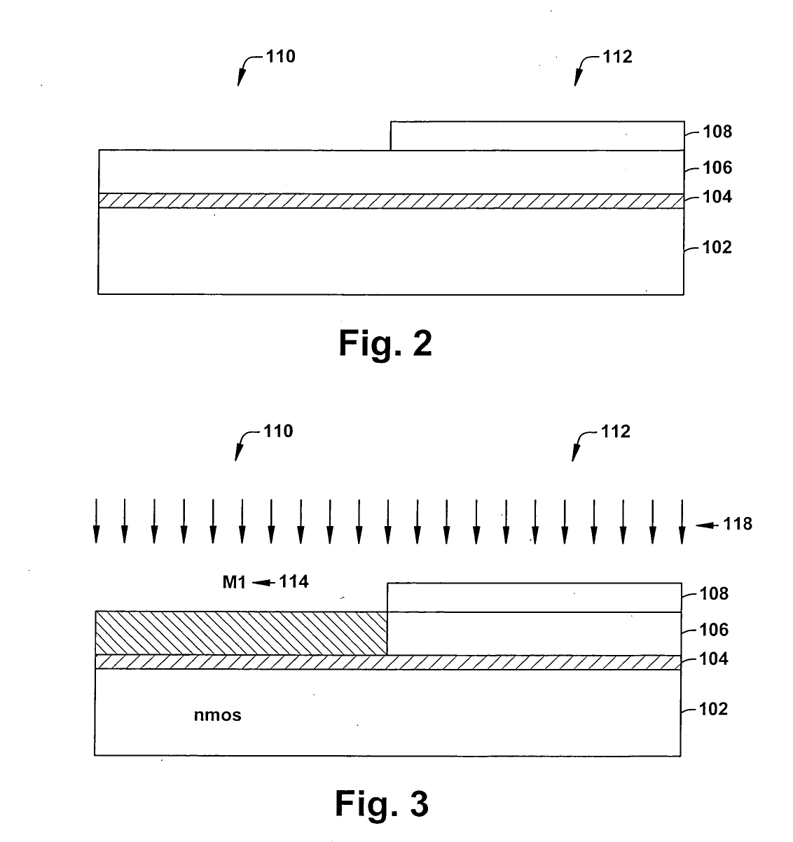

The methodology 10 begins at 12, wherein a semiconductor substrate 102 having a thin layer of dielectric material 104 and a layer of polysilicon 106 formed thereover is masked off by a first selectively patterned masking material 108 so that the polysilicon is exposed in a first region 110 and is covered by the patterned masking material 108 in a second region 112 (FIG. 2). It will be appreciated that ‘substrate’ as referred to herein may comprise any type of semiconductor body (e.g., formed of silicon or SiGe) such as a semiconductor wafer or one or more die on a wafer, as well as any other type of semiconductor and/or epitaxial layers associated therewith. The dielectric material can have a thickness of less than about 5 nanometers, for example, and may comprise silicon oxynitride and/or a high-k dielectric constant material, such as hafnium oxide, hafnium silicate, hafnium silicon oxynitride, for example. Similarly, the polysilicon 106 can have a thickness of between about 1 nanometers and about 100 nanometers, for example.

It will be appreciated that (as with all the masking or patterning described herein) the masking or patterning at 12 can be performed in any suitable manner, such as with lithographic techniques, for example, where lithography broadly refers to processes for transferring one or more patterns between various media. In lithography, a light sensitive resist coating (not shown) is formed over one or more layers to which a pattern is to be transferred. The resist coating is then patterned by exposing it to one or more types of radiation or light which (selectively) passes through an intervening lithography mask containing the pattern. The light causes the exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated. In this example, the patterned resist 108 remains over the polysilicon 106 in the second region 112.

At 14, a first metal M1 114 is added to the polysilicon 106 in the first region 110, such as by a deposition and/or implantation process 118, for example, where the patterned masking material 108 blocks the first metal M1 114 from coming in contact with the polysilicon 106 in the second region 112 (FIG. 3). As will be discussed, the first metal 114 is used to set or establish a particular work function in the first region 110. To establish a work function for an NMOS type transistor, for example, the first layer of metal 114 may comprise Sc, Y, La, Yb, Er, Cs, Ba, Ti, V, Fe, Nb, Cd, Sn, Hf, Ta, Zr, lanthanides and/or actinides, for example, and may have a work function of between about 3.0 eV and about 4.3 eV, for example.

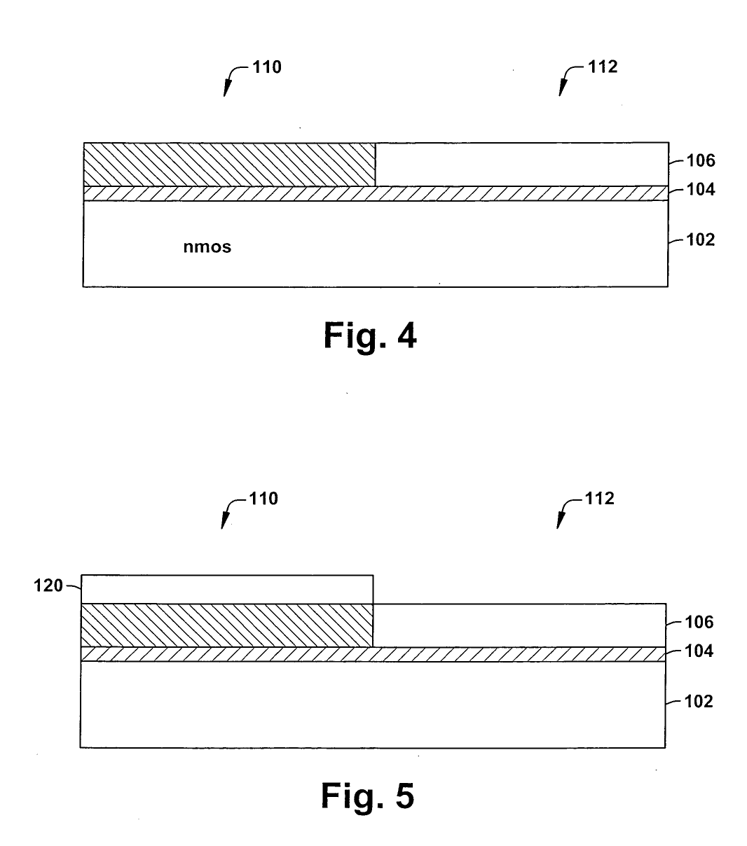

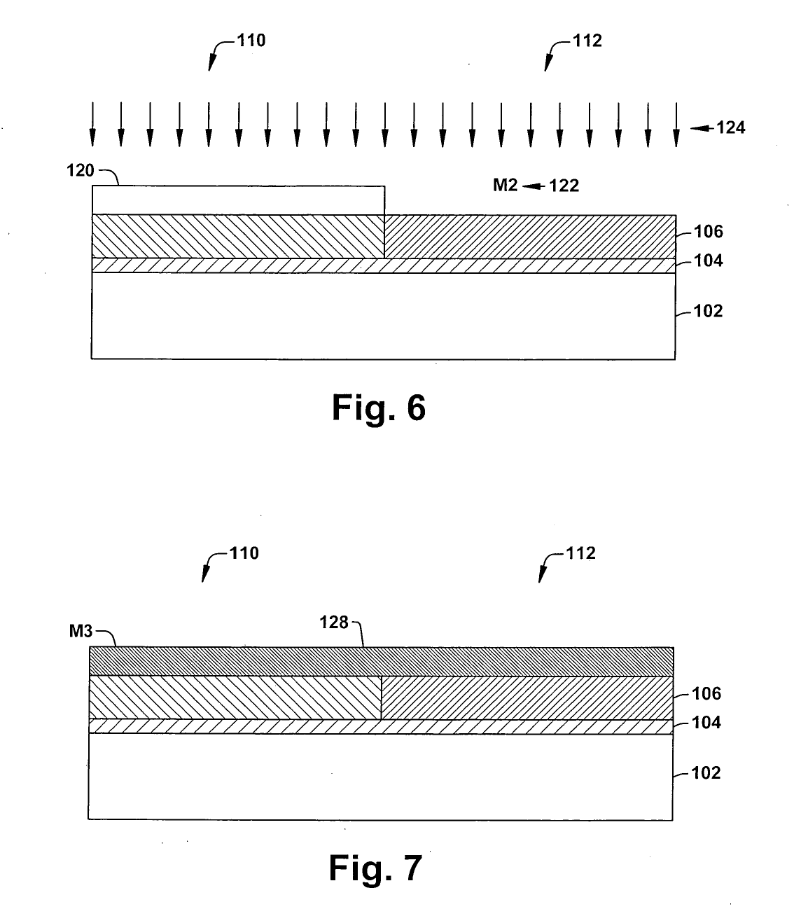

At 16, the patterned masking material 108 is stripped or otherwise removed from the second region 110 (FIG. 4). Then, at 18, a second selectively patterned masking material 120 is implemented to mask off the polysilicon 106 in the first region 110 while leaving the polysilicon 106 exposed in the second region 112 (FIG. 5). At 20, a second metal 122 is added to the polysilicon 106 in the second region 112, such as by a deposition and/or implantation process 124, for example, where the patterned masking material 120 blocks the second metal M2 122 from coming into contact with the polysilicon 106 in the second region 112 (FIG. 6). The second metal M2 122 is used to set or establish a particular work function in the second region 112. To establish a work function for a PMOS type transistor, for example, the second metal 122 may comprise Co, Ni, Se, Rh, Pd, Te, Re, Ir, Pt and/or Au, for example, and may have a work function of between about 4.8 eV and about 6.0 eV, for example.

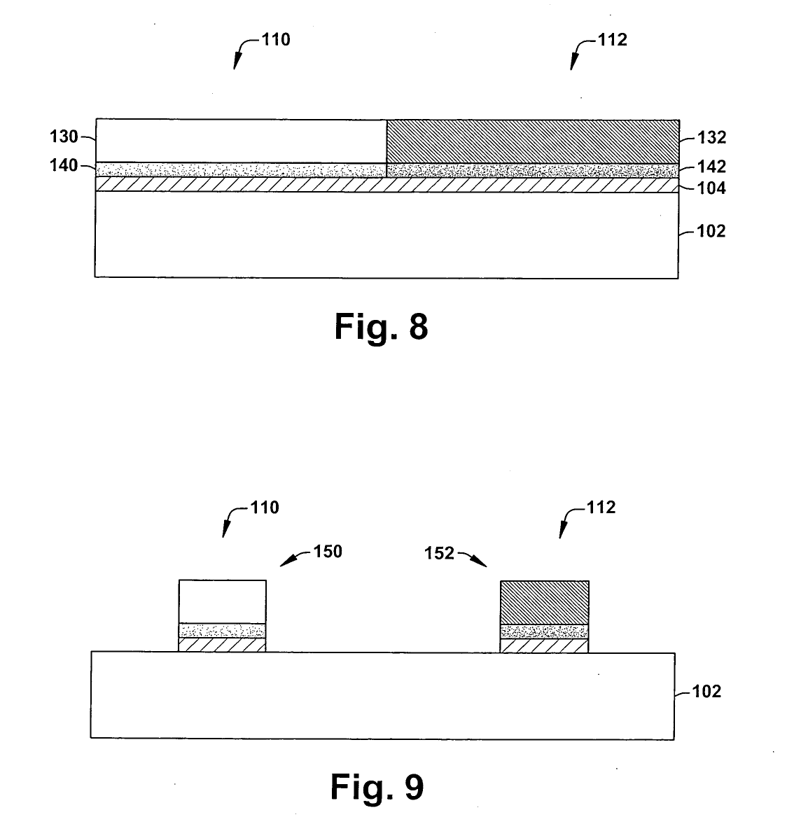

The second patterned masking material 120 is stripped or otherwise removed at 22, and a third metal 128 is formed (e.g., deposited) over the first 110 and second regions 112 at 24 (FIG. 7). The third metal 128 may be formed to a thickness of less than about 50 nanometers, for example, and is effective to form an alloy with the polysilicon 106 during a silicidation process. As such, the third metal 128 may comprise Ni, for example, to form NiSi alloys. Accordingly, one or more silicidation processes are performed at 26 wherein heat is applied (e.g., annealing) to form a first alloy 130 in the first region 110 and a second alloy 132 in the second region 112 (FIG. 8). It will be appreciated that, as with all silicidation (e.g., heating, annealing) processes described herein, this process can be performed in an inert ambient at a temperature of between about 300 and about 1000 degrees Celsius for between about 10 seconds to about 5 minutes, for example. Additionally, the resulting alloys may have respective thicknesses of about 100 nanometers or less, for example.

It will be appreciated that, according to one or more aspects of the present invention, the first 114 and second 122 metals are segregated out of the bulk polysilicon 106 and driven toward the dielectric 104 during the silicidation process. In this manner, first 140 and second 142 segregated regions are formed in the first 110 and second 112 regions, respectively, adjacent to the dielectric material 104. The presence of the first 114 and second 122 metals serves to alter respective work functions in the first 110 and second 112 regions, particularly after the silicidation process.

More particularly, a NiSi suicide generally has a (third) work function that falls somewhere in-between the respective work functions of NMOS (about 4 eV) and PMOS transistors (about 5 eV), and can thus be referred to as a mid gap work function. By way of example, the first metal 114 can shift the third work function down to a first work function in the first region 110, where the first work function can be close to about 4 eV so that one or more NMOS type transistors can be formed in the first region 110, for example. Similarly, the second metal 122 can shift the third work function up to a second work function in the second region 112, where the second work function can be close to about 5 eV so that one or more PMOS type transistors can be formed in the second region 112, for example.

It will be appreciated that the respective amounts of the first 114 and second 122 metals added to the polysilicon 106 in the first 110 and second 112 regions can be varied to adjust the respective sizes (e.g., thicknesses) of the resulting first 140 and second 142 segregated regions, which in turn adjusts the degree to which the first and second work functions are shifted in the first and second regions. This effectively provides a means for controlling the respective work functions in the first 110 and second 112 regions.

At 28, different transistor types are formed in the different regions 110, 112 (FIG. 9). For example, one or more NMOS type transistors can be fashioned in the first region 110, while one or more PMOS type transistors can be fashioned in the second region 112. Although not illustrated, it will be appreciated that a capping material, such as a nitride based material, for example, can be formed over the polysilicon to prevent certain atoms, such as boron dopant atoms, for example, from entering (e.g., being deposited into) the polysilicon. The capping material, first alloy 130, second alloy 132, first segregated region 140, second segregated region 142 and dielectric material 104 can be patterned to form first and second gate structures 150, 152 in the first 110 and second 112 regions, respectively, where the gate structures have a height of between about 50 to about 150 nanometers, for example.

Although not illustrated, it will be appreciated that remaining aspects of the transistors can then be formed by doping the substrate 102 to establish source and drain regions therein adjacent to the gate structures, thereby establishing respective channel regions under the gate structures between the source and drain regions. LDD, MDD, or other extension implants can also be performed, for example, depending upon the type(s) of transistors to be formed, and left and right sidewall spacers can be formed along left and right lateral sidewalls of the respective gate structures. Further metallization, and/or other back-end processing can also be subsequently performed.

Additionally, it will also be appreciated that the polysilicon 106, as well as the dielectric material 104, can be patterned before the first 114, second 122 and third 128 metals are added and the silicidation process is performed. In this scenario, selective masking/patterning may need to be implemented to inhibit these, as well as other, materials from being imparted into exposed regions of the substrate 102, for example. Also, separate annealing process can be performed for the first 110 and second 112 regions, where the third metal 128 would be selectively formed (e.g., utilizing a patterned masking material) over the first 110 and second 112 regions.

Additionally, it will be appreciated that other aspects of the transistor fabrication can also be done before first 114, second 122 and third 128 metals are added and the silicidation process is performed. These include doping the substrate 102 to establish source and drain regions therein adjacent to the gate structures, thereby establishing respective channel regions under the gate structures between the source and drain regions, LDD, MDD, or other extension implants, appropriate dopant activation anneals for source-drain, LDD and MDD dopants, and left and right sidewall spacer formation along left and right lateral sidewalls of the respective gate structures.

It can be appreciated that since the silicide(s) formed herein generally have a ‘mid gap’ work function that is modified by the first 114 and second 122 metals, forming different metal gate transistors as descried herein is advantageous because a relatively small work function shift (e.g., on the order of about 400 millivolts) is needed. Further, forming metal gate transistors as described herein can be implemented in a CMOS fabrication process in an efficient and cost effective manner.

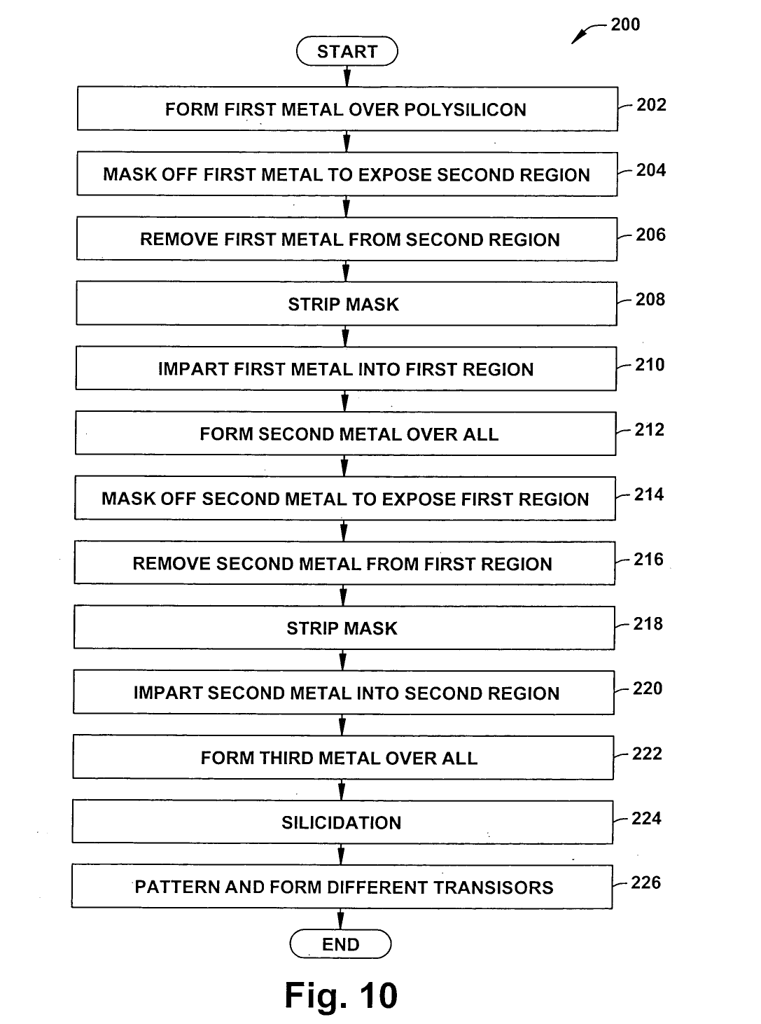

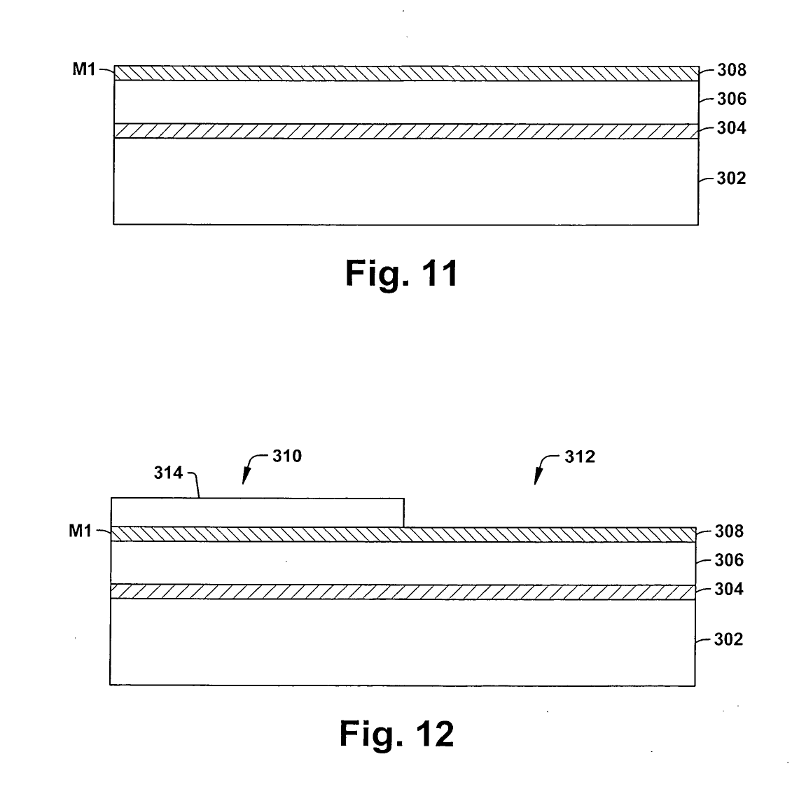

FIG. 10 illustrates another exemplary methodology 200 for forming metal gate transistors according to one or more aspects of the present invention. The methodology begins at 202 wherein a first metal M1 308 is formed (e.g., deposited) over a layer of polysilicon 306 that overlies a layer of dielectric material 304 on a semiconductor substrate 302 (FIG. 11). The dielectric material 304 may comprise silicon oxynitride and/or a high-k dielectric constant material, such as hafnium oxide, hafnium silicate, hafnium silicon oxynitride, for example, and can have a thickness of less than about 5 nanometers, for example. Similarly, the polysilicon 106 can have a thickness of between about 1 nanometers and about 100 nanometers, for example.

At 204, the first metal 308 is masked off in a in a first region 310 while remaining exposed in a second region 312 via a selectively patterned masking material 314 (FIG. 12). As will be discussed, the first metal 308 facilitates establishing a desired first work function in the first region 310. By way of example, the first metal 308 may comprise Sc, Ti, V, Fe, Nb, Cd, Sn, Hf, Ta, Zr, lanthanides and/or actinides, for example, to establish a first work function in the first region 310 that corresponds to an NMOS transistor (e.g., between about 3.0 eV and about 4.3 eV), for example.

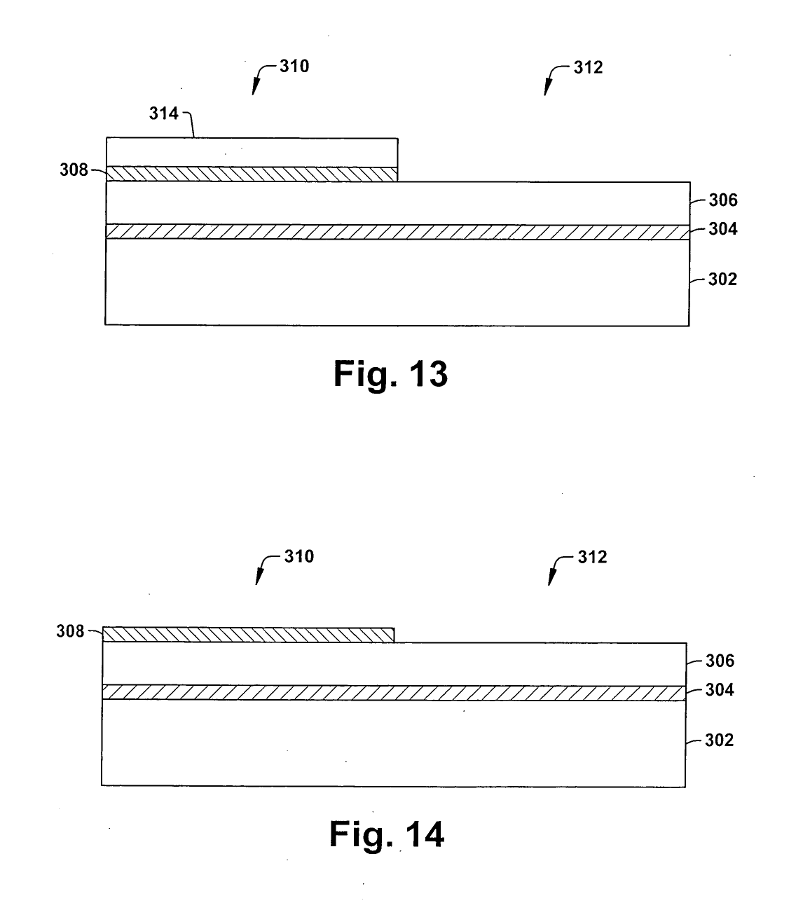

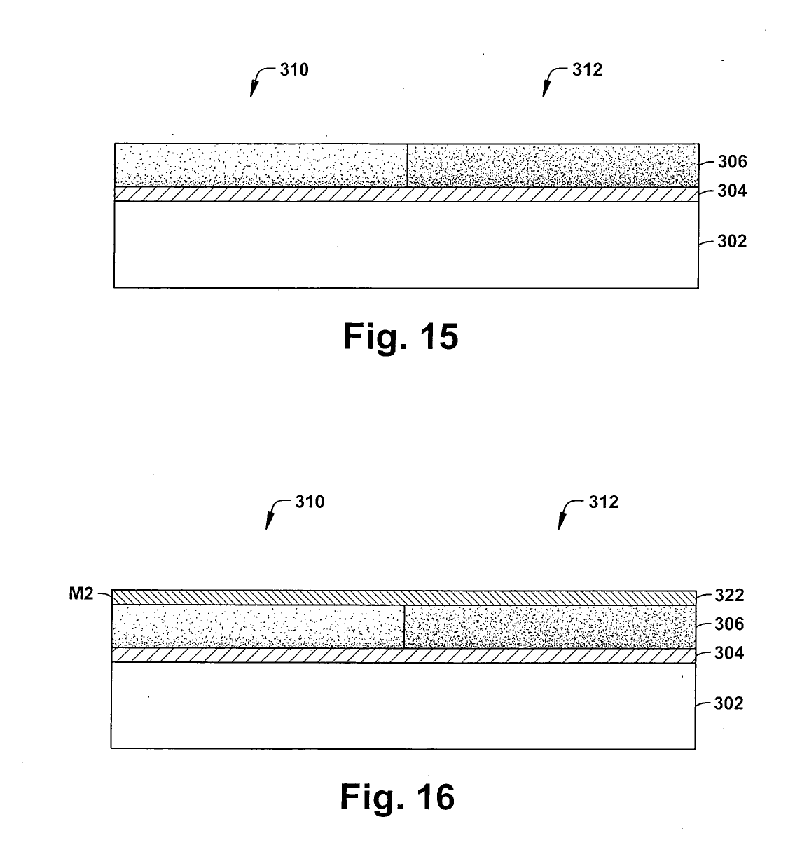

At 206, the first metal 308 is removed (e.g., etched away) in the second region 312 with the patterned masking material 314 protecting the first metal 308 in the first region 310 (FIG. 13). Then, the patterned masking material 314 is stripped or otherwise removed at 208 in the first region 310, leaving the first metal 308 over the polysilicon 306 in the first region 310 (FIG. 14). The first metal 308 is then imparted into the polysilicon 306 in the first region 310 at 210 (FIG. 15). This can be accomplished by an annealing process, for example, at a temperature of between about 300 and about 1000 degrees Celsius for between about 10 seconds to about 5 minutes, for example.

At 212, a second metal M2 322 is formed (e.g., deposited) over the first 310 and second 312 regions (FIG. 16). Similar to the first metal 308, the second metal 322 facilitates establishing a desired first work function in the second region 312. By way of example, the second metal 322 may comprise Be, Co, Ni, Se, Rh, Pd, Te, Re, Ir, Pt and/or Au, for example, to establish a work function corresponding to a PMOS type transistor in the second region 312 (e.g., between about 4.8 eV and about 6.0 eV).

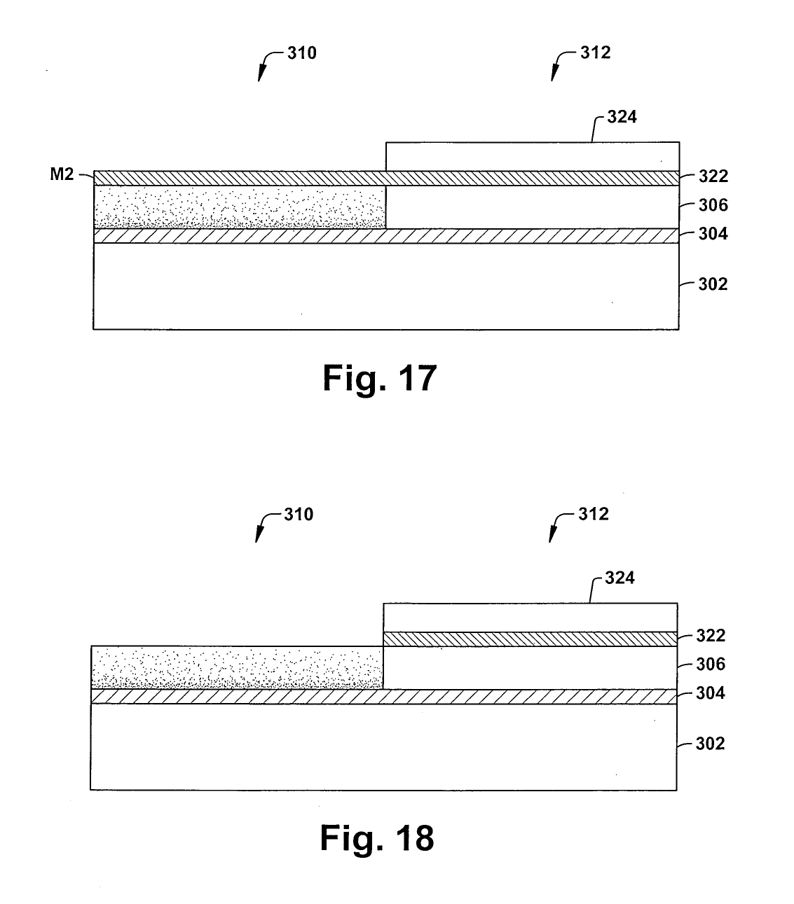

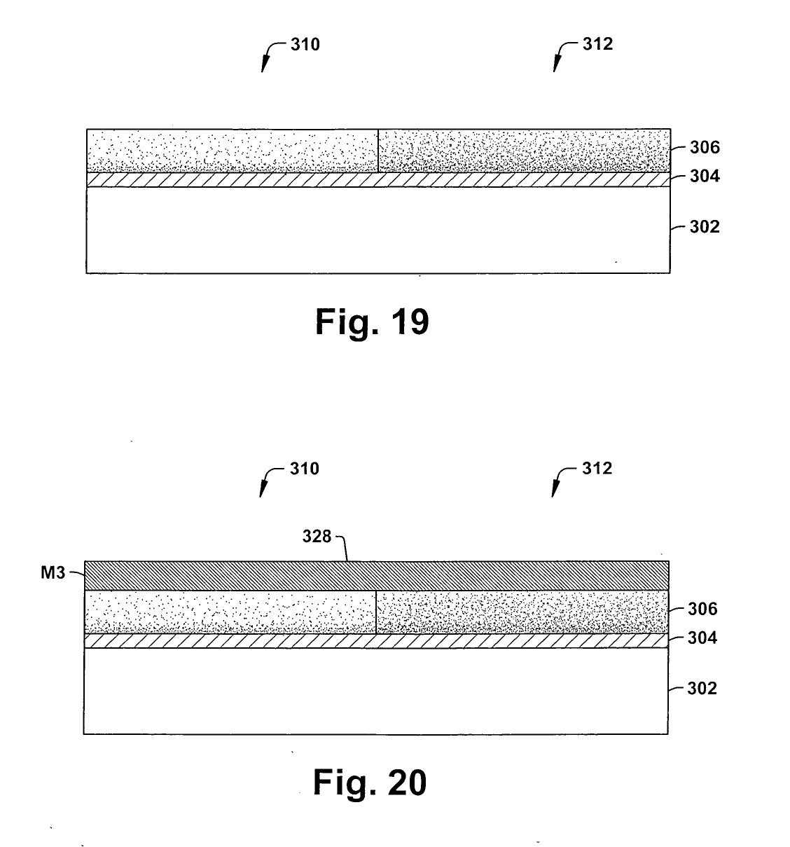

The second metal 322 is selectively masked off at 214 with a patterned masking material 324 such that the second metal 322 is exposed in the first region 310, but is covered by the patterned masking material 324 in the second region 312 (FIG. 17). At 216, the second metal 322 is removed (e.g., etched away) in the first region 310 with the patterned masking material 324 protecting the second metal 322 in the second region 312 (FIG. 18). The patterned masking material 324 is stripped or otherwise removed at 218, and the second metal 322 is imparted into the polysilicon 306 in the second region 312 at 220, such as by an annealing process, for example, (FIG. 19).

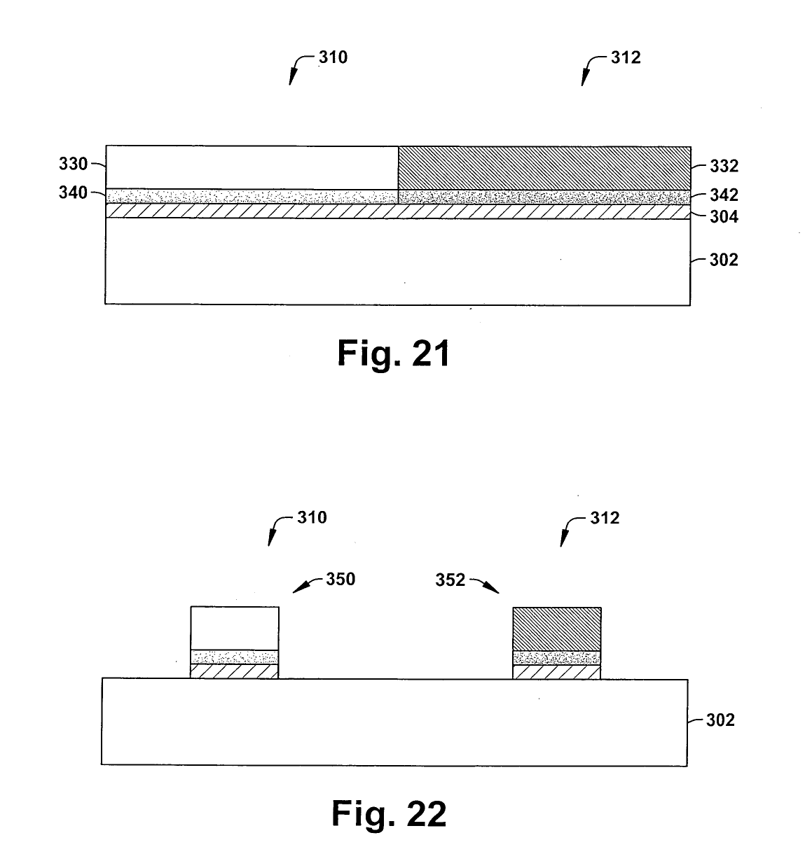

A third layer of metal M3 328 is then formed (e.g., deposited) over the first 310 and second 312 regions at 222 (FIG. 20). The third metal 328 may be formed to a thickness of less than about 50 nanometers, for example, and is effective to form an alloy with the polysilicon 306 during a silicidation process. As such, the third metal 328 may comprise Ni, for example, to form NiSi alloys. Accordingly, one or more silicidation processes are then performed at 224 wherein heat is applied to form a first alloy 330 in the first region 310 and a second alloy 332 in the second region 312, where the resulting alloys may have respective thicknesses of about 100 nanometers or less, for example, (FIG. 21).

It will be appreciated that, according to one or more aspects of the present invention, the first 308 and second 322 metals are segregated out of the bulk polysilicon 306 and driven toward the dielectric 304 during the silicidation process. In this manner, first 340 and second 342 segregated regions are formed in the first 310 and second 312 regions, respectively, adjacent to the dielectric material 304. The presence of the first 308 and second 322 metals serves to alter respective work functions in the first 310 and second 312 regions, particularly after the silicidation process.

More particularly, a NiSi silicide generally has a (third) work function that falls somewhere in-between the respective work functions of NMOS (about 4 eV) and PMOS transistors (about 5 eV), and can thus be referred to as a mid gap work function. By way of example, the first metal 314 can cause a work function in the first region 310 to be shifted down to about 4 eV so that one or more NMOS type transistors can be formed in the first region 310, for example. Similarly, the second metal 322 can cause a work function in the second region 312 to be shifted up to about 5 eV so that one or more PMOS type transistors can be formed in the second region 312, for example.

It will be appreciated that the respective thicknesses of the first 308 and second 322 metals can be varied to vary the amount of the first 308 and second 322 metals that are added to the polysilicon 306 in the first 310 and second 312 regions. This effectively governs the respective sizes (e.g., thicknesses) of the first 340 and second 342 segregated regions, which in turn adjusts the degree to which the respective work functions are shifted in the first 310 and second 312 regions. As such, this provides a means for controlling the resulting work functions in the first 310 and second 312 regions.

At 226, different transistor types are formed in the first 310 and second 312 regions (FIG. 22). For example, one or more NMOS type transistors can be fashioned in the first region 310, while one or more PMOS type transistors can be fashioned in the second region 312. Although not illustrated, it will be appreciated that a capping material, such as a nitride based material, for example, can be formed over the polysilicon to prevent certain atoms, such as boron dopant atoms, for example, from entering (e.g., being deposited into) the polysilicon. The capping material, first alloy 330, second alloy 332, first segregated region 340, second segregated region 342 and dielectric material 304 can be patterned to form first and second gate structures 350, 352 in the first 310 and second 312 regions, respectively, where the gate structures have a height of between about 50 to about 350 nanometers, for example.

Although not illustrated, it will be appreciated that remaining aspects of the transistors can then be formed by doping the substrate 302 to establish source and drain regions therein adjacent to the gate structures, thereby establishing respective channel regions under the gate structures between the source and drain regions. LDD, MDD, or other extension implants can also be performed, for example, depending upon the type(s) of transistors to be formed, and left and right sidewall spacers can be formed along left and right lateral sidewalls of the respective gate structures. Further metallization, and/or other back-end processing can also be subsequently performed.

Additionally, it will also be appreciated that the polysilicon 306, as well as the dielectric material 304, can be patterned before the first 308, second 322 and third 328 metals are added and the silicidation process is performed. In this scenario, selective masking/patterning may need to be implemented to inhibit these, as well as other, materials from being imparted into exposed regions of the substrate 302, for example. Further, the third metal 328 can be formed over the first 308 and second 322 metals before the first 308 and second 322 metals are imparted into the first 310 and second 312 regions. In such a scenario, the first 308 and second 322 metals may be imparted into the first 310 and second 312 regions concurrently with the formation of the first 330 and second 332 alloys and the first 340 and second 342 segregated regions.

Also, separate silicidation processes can be performed for the first 310 and second 312 regions, where the third metal 328 would be selectively formed (e.g., utilizing a patterned masking material) over the first 310 and second 312 regions.

As before, it will be appreciated that other aspects of the transistor fabrication can also be done before first 308, second 322 and third 328 metals are added and the silicidation process is performed. These include doping the substrate 302 to establish source and drain regions therein adjacent to the gate structures, thereby establishing respective channel regions under the gate structures between the source and drain regions, LDD, MDD, or other extension implants, appropriate dopant activation anneals for source-drain, LDD and MDD dopants, and left and right sidewall spacer formation along left and right lateral sidewalls of the respective gate structures.

As before, since the silicide(s) formed herein generally have a ‘mid gap’ work function that is modified by the first 308 and second 322 metals, forming different metal gate transistors as described herein is advantageous because a relatively small work function shift (e.g., on the order of about 400 millivolts) is needed. Further, forming metal gate transistors as described herein can be readily implemented in a CMOS fabrication process.

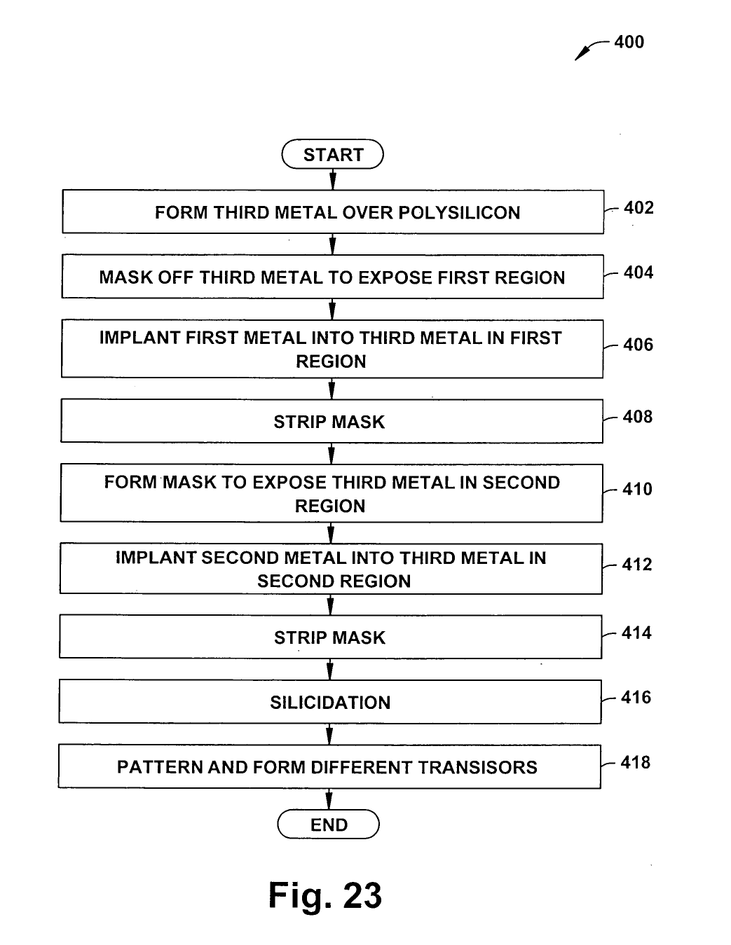

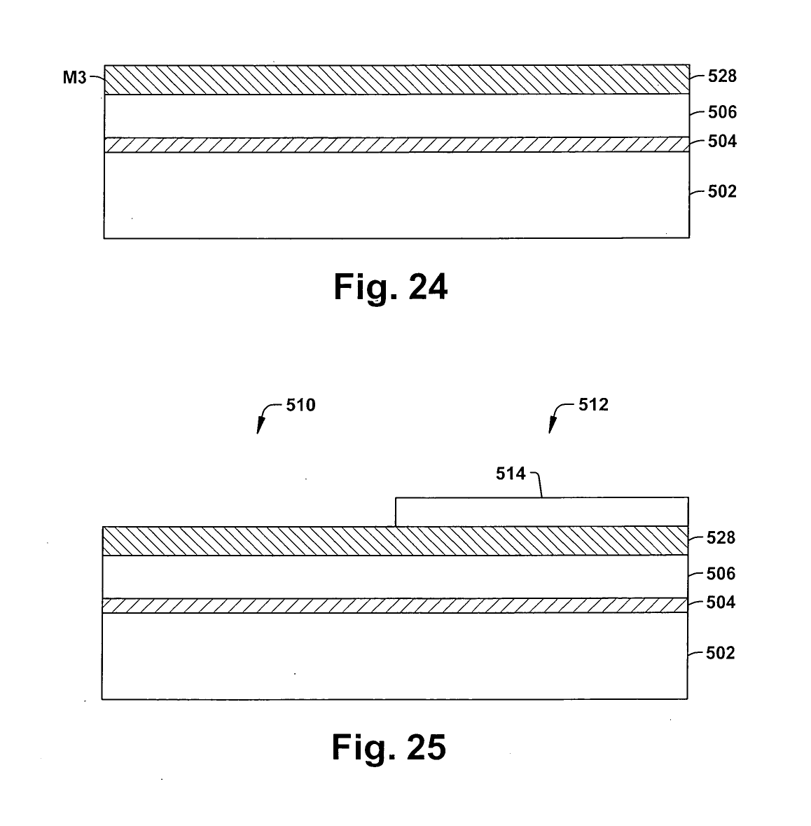

Turning to FIG. 23, yet another exemplary methodology 400 is illustrated for forming metal gate transistors according to one or more aspects of the present invention. The methodology begins at 402 wherein a third metal M3 528 is formed (e.g., deposited) over a layer of polysilicon 506 that overlies a layer of dielectric material 504 on a semiconductor substrate 502 (FIG. 24). The third metal 528 may be formed to a thickness of less than about 50 nanometers, for example, and is effective to form an alloy with the polysilicon 506 during a silicidation process. As such, the third metal 528 may comprise Ni, for example, to form NiSi alloys. The dielectric material 504 may comprise silicon oxynitride and/or a high-k dielectric constant material, such as hafnium oxide, hafnium silicate, hafnium silicon oxynitride, for example, and can have a thickness of less than about 5 nanometers, for example. Similarly, the polysilicon 506 can have a thickness of between about 1 nanometers and about 100 nanometers, for example.

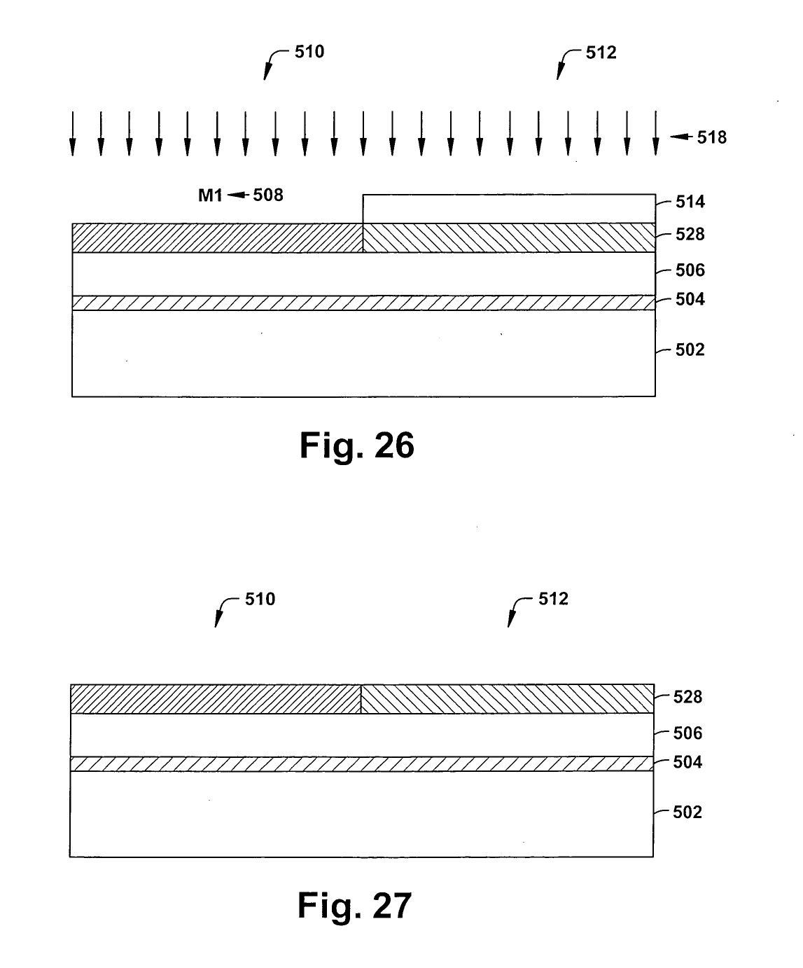

The third metal 528 is then masked off at 404 with a selectively patterned masking material 514 such that the third metal 528 is exposed in a first region 510 and is covered in a second region 512 (FIG. 25). At 406, a first metal M1 508 is imparted into the third metal 528 in the first region 510, such as by an implantation process 518, with the masking material 514 inhibiting the first metal 508 from entering the third metal 528 in the second region 512 (FIG. 26). The patterned masking material 514 is then removed at 408 (FIG. 27). It will be appreciated that the first metal 508 facilitates establishing a desired first work function in the first region 510. By way of example, the first metal 508 may comprise Sc, Ti, V, Fe, Nb, Cd, Sn, Hf, Ta, Zr, lanthanides and/or actinides, for example, to establish a first work function in the first region 510 that corresponds to an NMOS transistor (e.g., between about 3.0 eV and about 4.3 eV), for example.

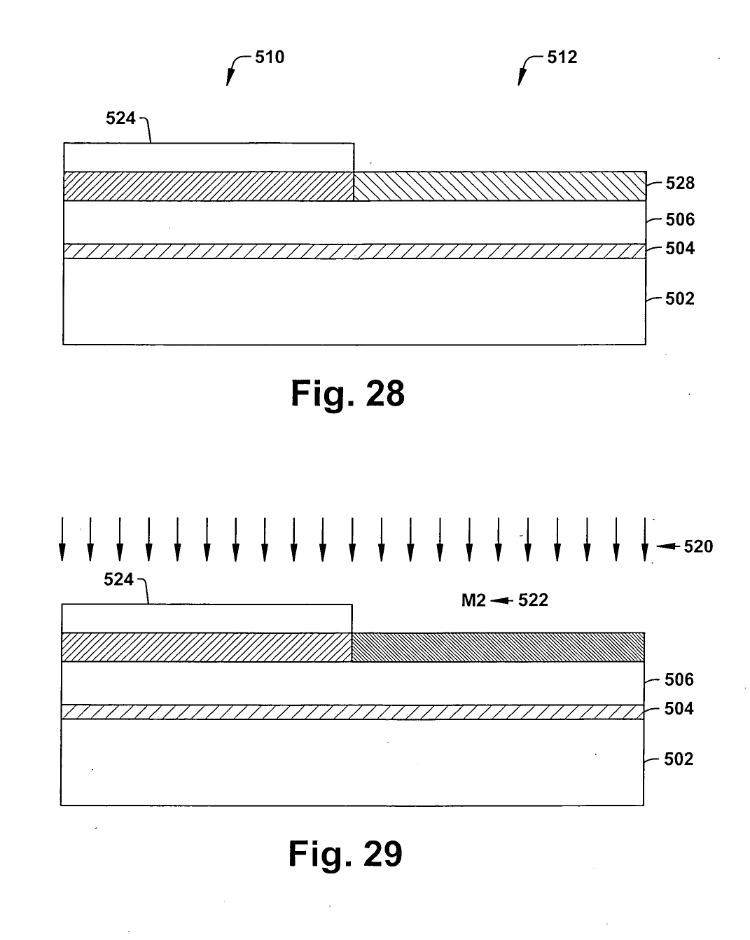

The third metal 528 is then masked off again at 410 with another selectively patterned masking material 524 (FIG. 28). The third metal 528 is masked off so that it is exposed in the second region 512 while being covered in the first region 510. At 412, a second metal M2 522 is imparted into the third metal 528 in the second region 512, such as by another implantation process 520, with the masking material 524 inhibiting the second metal 522 from entering the third metal 528 in the first region 510 (FIG. 29). It will be appreciated that the second metal 522 facilitates establishing a desired first work function in the second region 512. By way of example, the second metal 522 may comprise Be, Co, Ni, Se, Rh, Pd, Te, Ru, Re, Ir, Pt and/or Au, for example, to establish a work function corresponding to a PMOS type transistor in the second region 512 (e.g., between about 4.8 eV and about 6.0 eV).

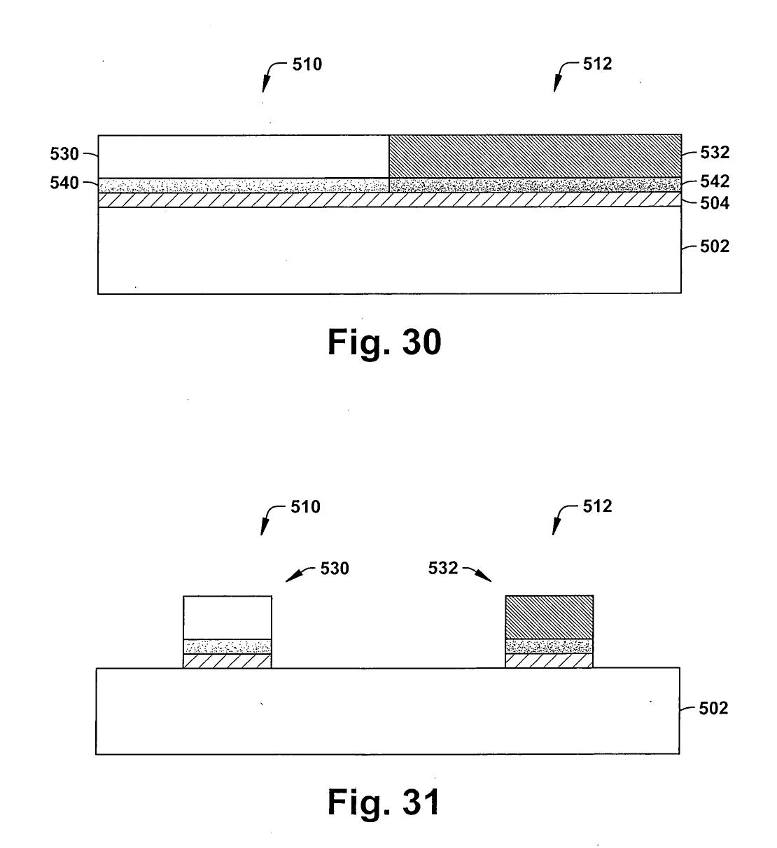

The patterned masking material 524 is then removed at 414, and one or more silicidation processes are performed at 416 to establish a first alloy 530 in the first region 510 and a second alloy 532 in the second region 512 (FIG. 30). It will be appreciated that first 540 and second 542 segregated regions are formed in the first 510 and second 512 regions adjacent to the dielectric 504 as a result of the silicidation process. More particularly, these regions 540, 542 are formed as a result of the first 508 and second 522 metals being segregated out during the silicidation process. The presence or activity of the first 508 and second 522 metals in the first 510 and second 512 regions, particularly during the silicidation process, can facilitate establishing a work function corresponding to an NMOS transistor in the first region 510 and a work function corresponding to a PMOS transistor in the second region 512, for example.

It will be appreciated that the respective amounts of the first 508 and second 522 metals added to the third metal 528 in the first 510 and second 512 regions can be varied to effectively govern the respective sizes (e.g., thicknesses) of the first 540 and second 542 segregated regions, which in turn adjusts the degree to which the respective work functions are shifted in the first 510 and second 512 regions. As such, this provides a means for controlling the resulting work functions in the first 510 and second 512 regions.

At 418, different transistor types are formed in the first 510 and second 512 regions (FIG. 31). For example, one or more NMOS type transistors can be fashioned in the first region 510, while one or more PMOS type transistors can be fashioned in the second region 512. Although not illustrated, it will be appreciated that a capping material, such as a nitride based material, for example, can be formed over the polysilicon to prevent certain atoms, such as boron dopant atoms, for example, from entering (e.g., being deposited into) the polysilicon. The capping material, first alloy 530, second alloy 532, first segregated region 540, second segregated region 542 and dielectric material 504 can be patterned to form first and second gate structures 550, 552 in the first 510 and second 512 regions, respectively, where the gate structures have a height of between about 50 to about 350 nanometers, for example.

Although not illustrated, it will be appreciated that remaining aspects of the transistors can then be formed by doping the substrate 502 to establish source and drain regions therein adjacent to the gate structures, thereby establishing respective channel regions under the gate structures between the source and drain regions. LDD, MDD, or other extension implants can also be performed, for example, depending upon the type(s) of transistors to be formed, and left and right sidewall spacers can be formed along left and right lateral sidewalls of the respective gate structures. Further metallization, and/or other back-end processing can also be subsequently performed.

Additionally, it will also be appreciated that the polysilicon 506, as well as the dielectric material 504, can be patterned before the first 508, second 522 and third 528 metals are added and the silicidation process is performed. In this scenario, selective masking/patterning may need to be implemented to inhibit these, as well as other, materials from being imparted into exposed regions of the substrate 502, for example. Also, separate annealing processes can be performed for the first 510 and second 512 regions. In another example, first 508 and second 522 metals may merely be formed (e.g., deposited) over the third metal 528, rather than being initially deposited into the third metal 528. In such a scenario, the first 508 and second 522 metals may be imparted into the first 510 and second 512 regions during the one or more processes that cause the first 530 and second 532 alloys and the first 540 and second 542 segregated regions to be formed.

In another example, the third metal 528 can be ‘added’ to the polysilicon 506, such as by one or more implantation and/or thermal processes, for example, and the first 508 and second 522 metals can then be added to this combination of the third metal 528 and the polysilicon 506. Silicidation can then be performed and different transistor types can be formed as before. Similarly, in another example, the first metal 508 can be combined with the third metal 528 to form a M1M3 alloy, and the second metal 522 metal can be combined with the third metal 528 to form a M2M3 alloy. The M1M3 alloy and the M2M3 alloy can then be applied (e.g., deposited) onto the polysilicon 506 in the first 510 and second 512 regions, respectively, such as by utilizing one or more selectively patterned masking materials in manner(s) previously described. Then, silicidation can be performed and different transistor types can be formed in the first 510 and second 512 regions as before.

Additionally, it will be appreciated that other aspects of the transistor fabrication can also be done before first 508, second 522 and third 528 metals are added and the silicidation process is performed. These include doping the substrate 502 to establish source and drain regions therein adjacent to the gate structures, thereby establishing respective channel regions under the gate structures between the source and drain regions, LDD, MDD, or other extension implants, appropriate dopant activation anneals for source-drain, LDD and MDD dopants, and left and right sidewall spacer formation along left and right lateral sidewalls of the respective gate structures.

As described above, it will be appreciated that since the silicide(s) formed herein generally have a ‘mid gap’ work function that is modified by the first 508 and second 522 metals, forming different metal gate transistors as descried herein is advantageous because a relatively small work function shift (e.g., on the order of about 400 milli volts) is needed. Further, forming metal gate transistors as described herein can be readily implemented in a CMOS fabrication process.

Accordingly, forming transistors according to one or more aspects of the present invention allows different types of metal gate transistors having different respective work functions to be concurrently formed in a single fabrication process. Forming the different types of transistors allows their respective advantages to be taken advantage of to satisfy different circuit application requirements. The metal gate transistors also allow feature sizes, such as dielectric thicknesses, for example, to be reduced to facilitate device scaling and increase packing densities.

It will be appreciated that while reference is made throughout this document to exemplary structures in discussing aspects of methodologies described herein (e.g., those structures presented in FIGS. 2-9 while discussing the methodology set forth in FIG. 1, structures presented in FIGS. 11-22 while discussing the methodology set forth in FIG. 10 and structures presented in FIGS. 24-31 while discussing the methodology set forth in FIG. 23), that those methodologies are not to be limited by the corresponding structures presented. Rather, the methodologies (and structures) are to be considered independent of one another and able to stand alone and be practiced without regard to any of the particular aspects depicted in the Figs.

It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. Additionally, unless stated otherwise and/or specified to the contrary, any one or more of the layers set forth herein can be formed in any number of suitable ways, such as with spin-on techniques, sputtering techniques (e.g., magnetron and/or ion beam sputtering), (thermal) growth techniques and/or deposition techniques such as chemical vapor deposition (CVD), physical vapor deposition (PVD) and/or plasma enhanced chemical vapor deposition (PECVD), or atomic layer deposition (ALD), for example, and can be patterned in any suitable manner (unless specifically indicated otherwise), such as via etching and/or lithographic techniques, for example. Further, the term “exemplary” as used herein merely meant to mean an example, rather than the best.

Although one or more aspects of the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and/or advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method of forming metal gate transistors, comprising:
selectively masking off a polysilicon overlying a dielectric on a semiconductor substrate so that the polysilicon is exposed in a first region, but not in a second region;
adding a first metal to the polysilicon in the first region, the first metal serving to shift a first work function in the first region;
selectively masking off the polysilicon so that the polysilicon is exposed in the second region, but not in the first region;
adding a second metal to the polysilicon in the second region, the second metal serving to shift a second work function in the second region;
forming a third metal over the first and second regions;
performing one or more silicidation operations to form a first alloy in the first region and a second alloy in the second region, the first and second metals being segregated out toward the dielectric as a result of the silicidation processes such that first and second segregated regions are established in the first and second regions, respectively, adjacent to the dielectric; and
forming one or more transistors in the first region and one or more transistors in the second region.

2. The method of claim 1, wherein at least one of:
the third metal comprises Ni,
the first metal comprises at least one of Sc, Y, La, Yb, Er, Cs, Ba, Ti, V, Fe, Nb, Cd, Sn, Hf, Ta, and Zr,
the first metal has a work function of between about 3.0 eV and about 4.3 eV,
the second metal comprises at least one of Be, Co, Ni, Se, Rh, Pd, Te, Ru, Re, Ir, Pt and/or Au,
the second metal has a work function of between about 4.8 eV and about 6.0 eV,
the dielectric is one of a high k dielectric or SiON, and
the first and second alloys have respective thicknesses of less than about 100 nanometers.

3. The method of claim 1, wherein forming one or more transistors in the first and second regions comprises forming a first gate structure in the first region and a second gate structure in the second region.

4. The method of claim 1, wherein at least one of:
the first work function is shifted to about 4 eV, and
the second work function is shifted to about 5 eV.

5. The method of claim 1, wherein at least one of:
at least one of the first and second metals are added to the polysilicon by at least one of a deposition and implantation process, and
the third metal is formed by a deposition process.

6. A method of forming metal gate transistors, comprising:
forming a first metal over a layer of polysilicon overlying a dielectric on a semiconductor substrate;
selectively masking off the first metal so that the first metal is exposed in a second region, but not in a first region;
removing the exposed first metal in the second region;
imparting the first metal into the polysilicon in the first region, the first metal serving to shift a first work function in the first region;
forming a second metal over the first and second regions;
selectively masking off the second metal so that the second metal is exposed in the first region, but not in the second region;
removing the exposed second metal in the first region;
imparting the second metal into the polysilicon in the second region, the second metal serving to shift a second work function in the second region;
forming a third metal over the first and second regions;
performing one or more silicidation operations to form a first alloy in the first region and a second alloy in the second region, the first and second metals being segregated out toward the dielectric as a result of the silicidation processes such that first and second segregated regions are established in the first and second regions, respectively, adjacent to the dielectric; and
forming one or more transistors in the first region and one or more transistors in the second region.

7. The method of claim 6, wherein the first and second metals are not imparted into the first and second regions, respectively, before the third metal is formed over the first and second regions.

8. The method of claim 6, wherein at least one of the first, second and third metals are deposited.

9. The method of claim 6, wherein at least one of:
the third metal comprises Ni,
the first metal comprises at least one of Sc, Y, La, Yb, Er, Cs, Ba, Ti, V, Fe, Nb, Cd, Sn, Hf, Ta and Zr,
the first metal has a work function of between about 3.0 eV and about 4.3 eV,
the second metal comprises at least one of Be, Co, Ni, Se, Rh, Pd, Te, Ru, Re, Ir, Pt and/or Au,
the second metal has a work function of between about 4.8 eV and about 6.0 eV,
the dielectric is one of a high k dielectric and SiON, and
the first and second alloys have respective thicknesses of less than about 100 nanometers.

10. The method of claim 6, wherein forming one or more transistors in the first and second regions comprises forming a first gate structure in the first region and a second gate structure in the second region.

11. The method of claim 6, wherein at least one of:
the first work function is shifted to about 4 eV, and
the second work function is shifted to about 5 eV.

12. A method of forming metal gate transistors, comprising:
forming a third metal over a layer of polysilicon overlying a dielectric on a semiconductor substrate;
selectively masking off the third metal so that the third metal is exposed in a first region, but not in a second region;
applying a first metal to the first region, the first metal serving to shift a first work function in the first region;
selectively masking off the third metal so that the third metal is exposed in a second region, but not in a first region;
applying a second metal to the second region, the second metal serving to shift a second work function in the second region;
performing one or more silicidation operations to form a first alloy in the first region and a second alloy in the second region, the first and second metals being segregated out toward the dielectric as a result of the silicidation processes such that first and second segregated regions are established in the first and second regions, respectively, adjacent to the dielectric; and
forming one or more transistors in the first region and one or more transistors in the second region.

13. The method of claim 12, wherein at least one of the first and second metals are implanted to be applied to the first and second regions, respectively.

14. The method of claim 12, wherein at least one of the first and second metals are deposited to be applied to the first and second regions, respectively.

15. The method of claim 12, wherein the third metal is imparted into the polysilicon before the first and second metals are applied.

16. The method of claim 12, wherein, initially, the first metal and the third metal are combined to form an M1M3 alloy and the second metal and the third metal are combined to form an M2M3 alloy, and the M1M3 alloy is then selectively applied to the first region and the M2M3 alloy is selectively applied to the second region.

17. The method of claim 12, wherein at least one of at least one of the first and second metals are added to the polysilicon by at least one of a deposition process and an implantation process and the third metal is formed by a deposition process

18. The method of claim 12, wherein at least one of:
the third metal comprises Ni,
the first metal comprises at least one of Sc, Y, La, Yb, Er, Cs, Ba, Ti, V, Fe, Nb, Cd, Sn, Hf, Ta and Zr,
the first metal has a work function of between about 3.0 eV and about 4.3 eV,
the second metal comprises at least one of Be, Co, Ni, Se, Rh, Pd, Te, Ru, Re, Ir, Pt and/or Au,
the second metal has a work function of between about 4.8 eV and about 6.0 eV,
the dielectric is one of a high k dielectric and SiON, and
the first and second alloys have respective thicknesses of less than about 100 nanometers.

19. The method of claim 12, wherein forming one or more transistors in the first and second regions comprises forming a first gate structure in the first region and a second gate structure in the second region.

20. The method of claim 12, wherein at least one of:
the first work function is shifted to about 4 eV, and
the second work function is shifted to about 5 eV.
